(19) United States
(12) Patent Application Publication
(10) Pub. No.: US 2013/0221321 A1
(43) Pub. Date: Aug. 29, 2013

(54) LIGHT-EMITTING DIODE DEVICE

(71) Applicants: Jinn Kong Sheu, Tainan City (TW); Chih-Yuan Chang, Tainan City (TW); Heng Liu, Sunnyvale, CA (US); Wei-Chih Lai, Tainan City (TW)

(72) Inventors: Jinn Kong Sheu, Tainan City (TW); Chih-Yuan Chang, Tainan City (TW); Heng Liu, Sunnyvale, CA (US); Wei-Chih Lai, Tainan City (TW)

(73) Assignee: PHOSTEK, INC., Taipei City (TW)

(21) Appl. No.: 13/464,656

(22) Filed: May 4, 2012

(30) Foreign Application Priority Data
Feb. 24, 2012 (TW) 101106134

(51) Int. Cl. H01L 33/04

(52) U.S. Cl. 257/13; 257/E33.008

(57) ABSTRACT

A light-emitting diode (LED) device includes a first LED, a second LED, and a superlattice structure by which the first and the second LEDs are stacked. The superlattice structure has an absorption spectra, the first active layer of the first LED has a first emission spectra, and the second active layer of the second LED has a second emission spectra. The absorption spectra is located on a shorter-wavelength side of at least one of the first and the second emission spectra.

### BACKGROUND OF THE INVENTION

1. Field of the Invention

The present invention generally relates to a light-emitting diode (LED) device, and more particularly to a LED device with a superlattice tunnel junction.

2. Description of Related Art

One of the methods for increasing emission efficiency of a light-emitting diode (LED) is using a tunnel junction to stack up two or more LEDs. The stacked LEDs emit more light than a single LED, and thus, have an increased brightness. The tunnel junction may enhance current spreading such that more carriers are available in an active layer for recombination. Further, the stacked LEDs have less electrode contact than individual LEDs of the same quantity. Less electrode contact may save more area and lessen electromigration phenomenon.

Conventional stacked LEDs with the tunnel junction may still, however, have emission efficiency problems and improvement in the emission efficiency is desired. Thus, there is a need for a novel LED structure with higher emission efficiency.

### SUMMARY OF THE INVENTION

In certain embodiments, a light-emitting diode (LED) device has a superlattice structure as a tunnel junction to increase emission efficiency. In certain embodiments, a better tunneling efficiency is achieved by adjusting indium and/or aluminum concentrations in the superlattice structure.

In certain embodiments, an LED unit of an LED device includes a first LED, a second LED and a superlattice structure. The first LED includes an n-side nitride semiconductor layer, a first active layer and a p-side nitride semiconductor layer. The second LED includes an n-side nitride semiconductor layer, a second active layer, and a p-side nitride semiconductor layer. The superlattice structure may include alternating layers of at least one first sub-layer and at least one second sub-layer. The superlattice structure may be located between the p-side nitride semiconductor layer of the first LED and the n-side nitride semiconductor layer of the second LED. The superlattice structure may provide a tunnel junction between the first LED and the second LED. The superlattice structure has an absorption spectra, the first active layer has a first emission spectra, and the second active layer has a second emission spectra. The absorption spectra is located on a shorter-wavelength side of at least one of the first and the second emission spectra.

### BRIEF DESCRIPTION OF THE DRAWINGS

FIG. 1 shows a cross section of an embodiment of a light-emitting diode (LED) device.

FIG. 2A shows current-voltage curves associated with varied aluminum concentrations when the indium concentration is 0.15%.

FIG. 2B shows current-voltage curves associated with varied polarization extent when the indium concentration is 0.15% and the aluminum concentration is 0.3%.

FIG. 2C shows current-voltage curves associated with varied polarization extent when the indium concentration is 0.15% and the aluminum concentration is 0.35%.

FIG. 3 shows current-voltage curves associated with varied aluminum concentrations when the indium concentration is 0.2% and the polarization extent is 40%.

FIG. 4 shows a relationship between retinal response and wavelength.

FIG. 5A to FIG. 5C show relationships between an emission spectra and an absorption spectra.

FIG. 6 shows a perspective diagram illustrating an embodiment of an LED device.

### DETAILED DESCRIPTION OF THE INVENTION

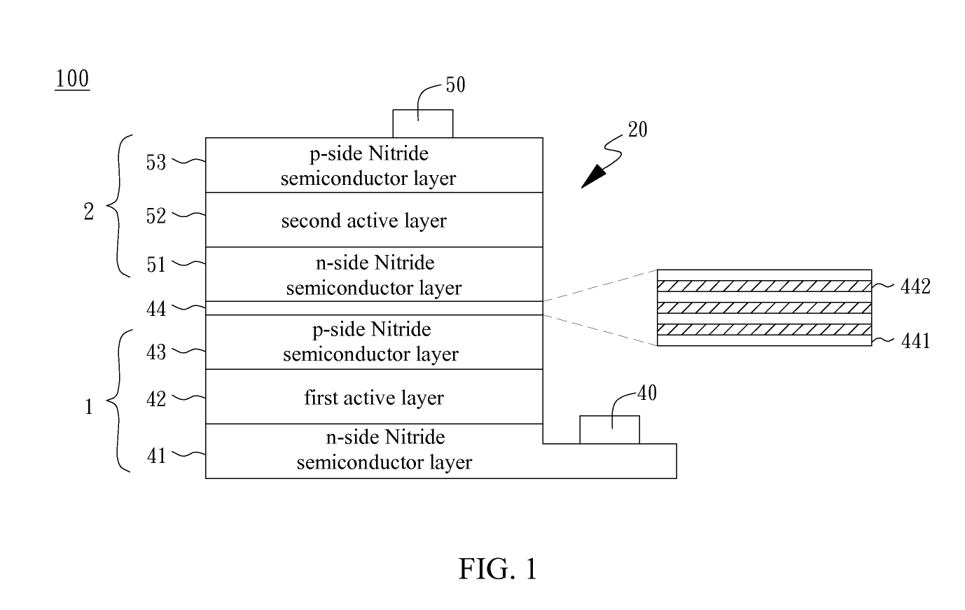

FIG. 1 shows a cross section of an embodiment of light-emitting diode (LED) device 100. For better appreciating the embodiment, drawings show layers that are most pertinent to the embodiment. LED device 100 includes at least one LED unit 20, and each LED unit includes at least one LED. In certain embodiments, LED unit 20 includes first LED 1 and second LED 2. First LED 1 primarily includes n-side nitride semiconductor layer 41, first active layer 42, p-side nitride semiconductor layer 43, and first electrode 40. In certain embodiments, first active layer 42 is placed between n-side nitride semiconductor layer 41 and p-side nitride semiconductor layer 43 and first electrode 40 is placed on the n-side nitride semiconductor layer. In some embodiments, n-side nitride semiconductor layer 41 includes n-type gallium nitride (GaN), first active layer 42 includes indium gallium nitride (InGaN), and p-side nitride semiconductor layer 43 includes p-type gallium nitride. First electrode 40 may be electrically connected to the n-type gallium nitride.

Second LED 2 may include n-side nitride semiconductor layer 51, second active layer 52, p-side nitride semiconductor layer 53, and second electrode 50. In certain embodiments, second active layer 52 is placed between n-side nitride semiconductor layer 51 and p-side nitride semiconductor layer 53. Second electrode 50 may be placed on p-side nitride semiconductor layer 53. In some embodiments, n-side nitride semiconductor layer 51 includes n-type gallium nitride, second active layer 52 includes indium gallium nitride, and p-side nitride semiconductor layer 53 includes p-type gallium nitride. Second electrode 50 may be electrically connected to the p-type gallium nitride.

In certain embodiments, superlattice structure 44 is formed between first LED 1 and second LED 2. Superlattice structure 44 acts as a tunnel junction that stacks first LED 1 with second LED 2 in order to increase emission efficiency (e.g., the superlattice structure provides a tunnel junction between the first LED and the second LED). Superlattice structure 44 may be formed by alternating at least one first sub-layer 441 (e.g., aluminum gallium nitride (AlGaN)) and at least one second sub-layer 442 (e.g., indium gallium nitride). For example, alternating layers of first sub-layer 441 and second sub-layer 442 may form superlattice structure 44. In some embodiments, alternating first sub-layers 441 and second sub-layers 442 may be one of the following alternating pairs of layers: AlGaN/InGaN, AlGaN/GaN, and GaN/InGaN.

Superlattice structure 44 may include, as shown in FIG. 1, three pairs of first sub-layer 441 and second sub-layer 442. The number of pairs of alternating layers may, however, be varied. In certain embodiments, the thickness of first sub-layer 441 or second sub-layer 442 is between about 1 nm and about 10 nm. Aluminum gallium nitride may generate tensile-strain piezoelectric polarization and indium gallium nitride may generate compressive-strain piezoelectric polarization (e.g., polarization that is opposite to the tensile-strain piezoelectric polarization). Because of the two opposite polarizations, the tunneling efficiency of superlattice structure 44 may be increased by adjusting a concentration of aluminum and/or indium.

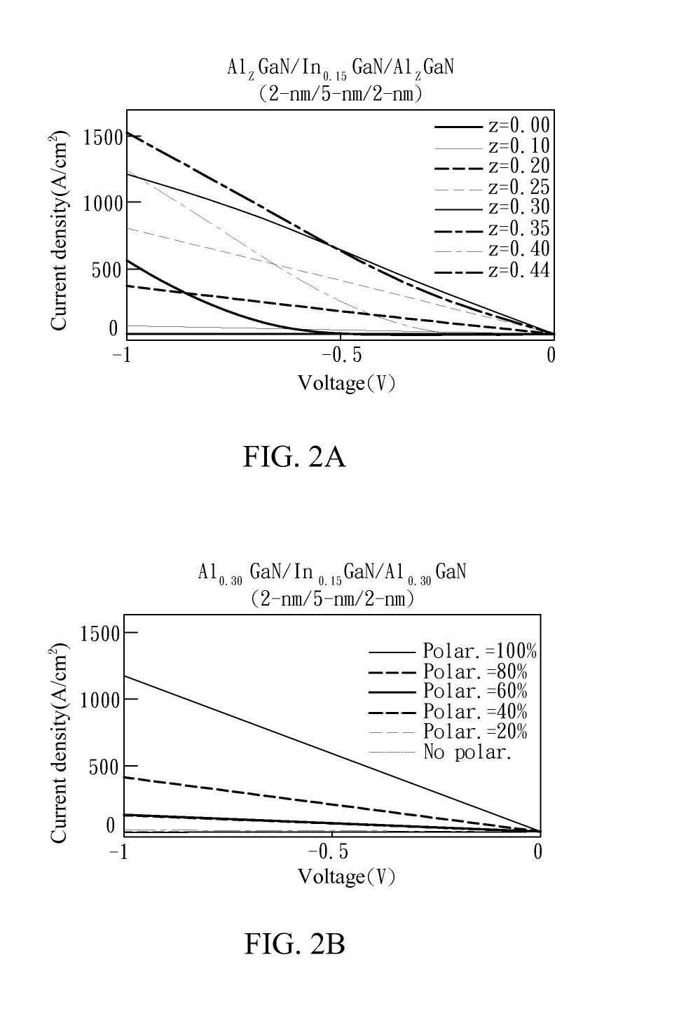

As light absorption effect becomes remarkable when the indium concentration is higher than 20% (or 0.2), the indium concentration of certain embodiments, is set below or equal to 20%. In certain embodiments, the indium concentration is set at 15% (or 0.15). FIG. 2A shows current-voltage curves associated with varied aluminum concentrations, z, when the indium concentration is 0.15. Generally speaking, superlattice structure 44 may generate a proper tunneling efficiency if the current density has a value higher than or equal to 50 A/cm² when the voltage has a value of −1, in addition to consideration to the extent of polarization. Accordingly, in certain embodiments, the aluminum concentration is between 0.2 and 0.44 (20% and 44%) (e.g., between 0.25 and 0.35 (25% and 35%)).

FIG. 2B shows current-voltage curves associated with varied polarization extent when the indium concentration is 0.15 and the aluminum concentration is 0.3. First sub-layer 441 includes Al_{0.3}Ga_{0.7}N and second sub-layer 442 includes In_{0.15}Ga_{0.85}N. According to the curves as shown, a proper tunneling efficiency may be obtained when the polarization extent is equal to or above 60%.

FIG. 2C shows current-voltage curves associated with varied polarization extent when the indium concentration is 0.15 and the aluminum concentration is 0.35. First sub-layer 441 includes Al_{0.35}Ga_{0.65}N and second sub-layer 442 includes In_{0.15}Ga_{0.85}N. According to the curves as shown, a proper tunneling efficiency may be obtained when the polarization extent is equal to or above 60%.

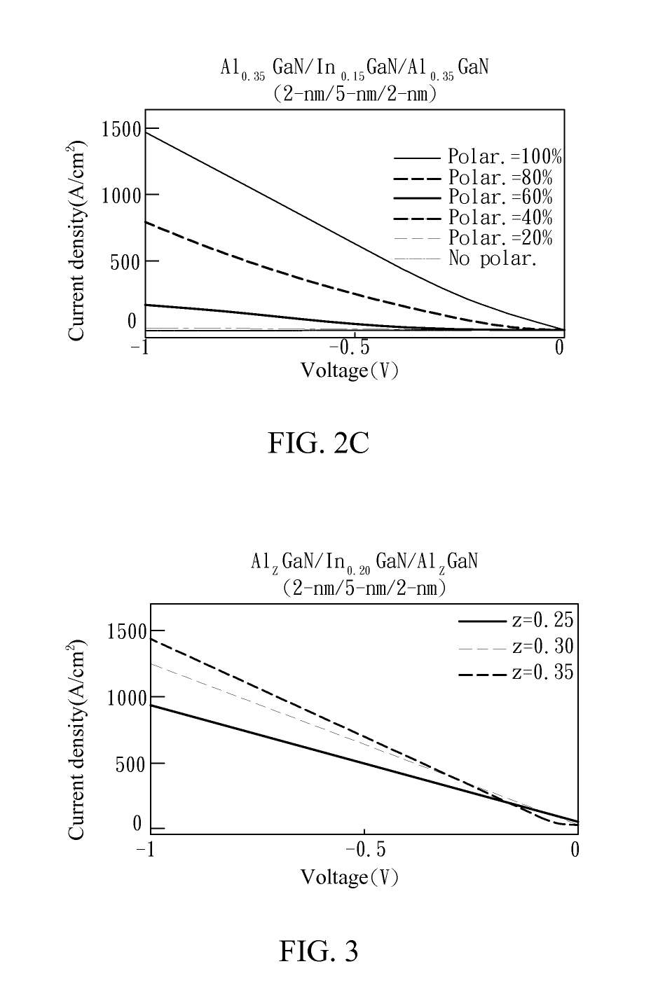

In some embodiments, a proper tunnel junction is obtained with a low polarization extent (e.g., less than 50%) by increasing the indium concentration (e.g., up to 20% or 0.2). FIG. 3 shows current-voltage curves associated with varied aluminum concentrations, z, when the indium concentration is 0.2. According to the curves as shown, a proper tunneling efficiency may be obtained with the aluminum concentration of 0.25-0.35 and a polarization extent as low as 40%.

In some embodiments, the ternary aluminum gallium nitride and/or indium gallium nitride of first sub-layer 441/second sub-layer 442 of superlattice structure 44 is replaced with quaternary aluminum indium gallium nitride (AlInGaN). The tunneling efficiency of superlattice structure 44 may be increased by adjusting an indium concentration and/or an aluminum concentration of first sub-layer 441/second sub-layer 442.

In certain embodiments, first active layer 42 of first LED 1 and second active layer 52 of second LED 2 are made of a same material and a same concentration such that the first LED and the second LED emit light at substantially the same wavelength. In some embodiments, first active layer 42 of first LED 1 and second active layer 52 of second LED 2 are made of different materials or different concentrations such that the first LED and the second LED emit light at different wavelengths. Details may be referred, for example, to U.S. Pat. No. 6,822,991 to Collins et al., entitled “Light emitting devices including tunnel junctions,” disclosure of which is incorporated by reference as if fully set forth herein.

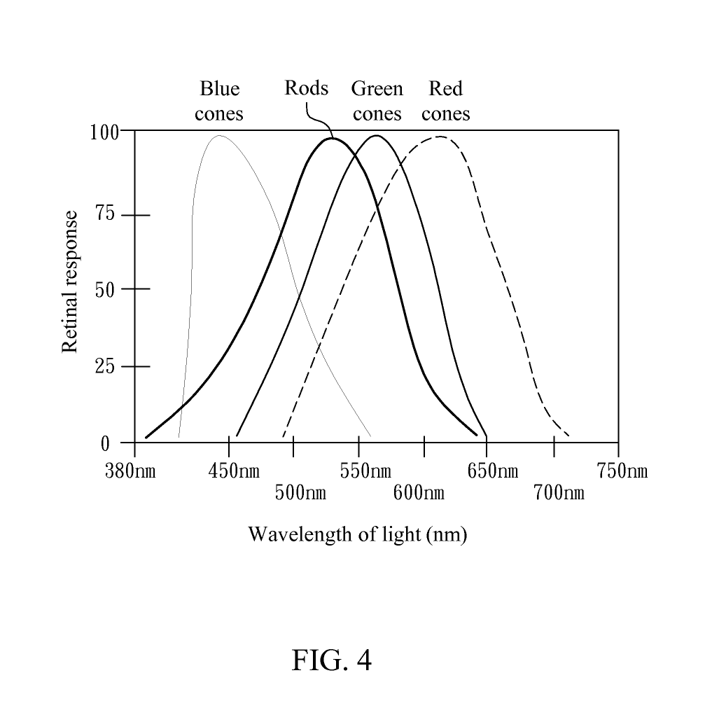

First/second active layer 42/52 made of indium gallium nitride may emit light ranging from blue light to green light (445-575 nm), as shown in FIG. 4, by adjusting its indium concentration. At least four wavelength combinations may be employed:

(1) stacking LEDs of different colors, for example, one blue LED (470 nm) and one green LED (550 nm);

(2) stacking LEDs of a same color and a same wavelength, for example, five blue LEDs (470 nm);

(3) stacking LEDs of a same color but different wavelengths, for example, five blue LEDs of 460 nm, 470 nm, 480 nm, 490 nm and 500 nm; and

(4) any combination of (1) to (3) illustrated above, for example, (1)+(3) five blue LEDs of 460 nm, 470 nm, 480 nm, 490 nm and 500 nm and five green LEDs of 510 nm, 520 nm, 530 nm, 540 nm and 550 nm.

A white LED may be formed according to one of (1)-(4) described above by using phosphor or other luminescence material in combination with the stacked LEDs. For example, the stacked ten LEDs (i.e., five blue LEDs of 460 nm, 470 nm, 480 nm, 490 nm, 500 nm and five green LEDs of 510 nm, 520 nm, 530 nm, 540 nm, 550 nm) in combination with a proper amount of red phosphor and yellow phosphor may result in a white LED with a high color rendering index (CRI).

A CRI value indicates relative difference between a color produced by a light source (to be measured) illuminating an object and a color produced by a reference light source. Specifically, the CRI value is measured by comparing and quantifying the difference between results respectively obtained by a light source to be measured and a reference light source by illuminating eight samples as specified in DIN (Deutsches Institut für Normung, or German Institute for Standardization) 6169. Less difference indicates higher color rendering of the light source to be measured. A light source with a CRI of 100 may produce color substantially the same as being produced by the reference light source. A light source with a lower CRI produces a distorted color. For example, sunlight has a CRI of 100 and a fluorescent light has a CRI of 60-85. Practically speaking, a light source with a CRI higher than 85 may be adapted in most applications.

A white LED is typically made up of a blue LED chip in combination with yellow phosphor (e.g., yttrium aluminum garnet or YAG) and is commonly called due-wavelength white LED, which has low color rendering. A tri-wavelength white LED packages a blue LED in combination with red and green phosphor. As the tri-wavelength white LED involves primary red, green, and blue colors, it typically has higher color rendering (with CRI normally higher than 85) than the due-wavelength white LED (with CRI normally less than 70). A quadric-wavelength white length has further higher color rendering with CRI higher than 95.

In certain embodiments, superlattice structure 44 acts as a tunnel junction to stack first LED 1 (which includes first active layer 42) and second LED 2 (which includes second active layer 52). In order to provide better tunneling effectiveness, first/second sub-layers 441/442 of superlattice structure 44 may contain a material similar to that of first/second active layers 42/52 to produce light absorption or emission. For example, indium gallium nitride of superlattice structure 44 may absorb the emitted light of first LED 1 and/or second LED 2, therefore affecting overall brightness or quality of the LED device.

As described above, LED device 100 includes, from bottom to top, first active layer 42, superlattice structure 44, and second active layer 52. Superlattice structure 44 has an absorption spectra, first active layer 42 has a first emission spectra, and second active layer 52 has a second emission spectra. In order to eliminate or reduce the light absorption phenomenon, the absorption spectra of superlattice structure 44 should be located on a shorter-wavelength side of the first emission spectra of first active layer 42 and/or the second emission spectra of second active layer 52.

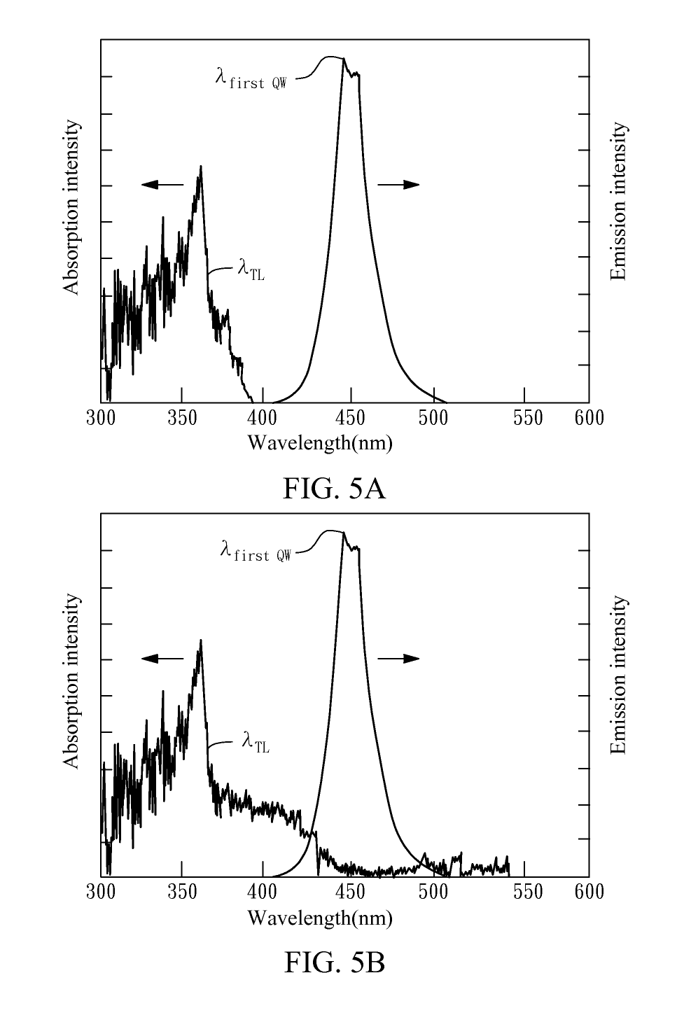

Taking the first emission spectra as an example, the absorption spectra of the superlattice structure 44 has one of the following three relationships with the first emission spectra: (1) the two spectra have almost no overlap with each other; (2) the two spectra overlap each other with slight overlapping (less than or equal to 40%); or (3) the two spectra overlap each other with significant overlapping (greater than 40%). FIG. 5A illustrates relationship (1). As shown in FIG. 5A, the light absorption phenomenon affecting first active layer 42 may be neglected. FIG. 5B illustrates relationship (2). As shown in FIG. 5B, the light absorption phenomenon affecting first active layer 42 may not be neglected but may be reduced by reducing total thickness of an indium-containing sub-layer(s) below or equal to 10 nm. FIG. 5C illustrates relationship (3). As shown in FIG. 5C, the light absorption phenomenon affecting first active layer 42 is substantial but may be reduced by reducing the total thickness of an indium-containing sub-layer(s) below or equal to 5 nm. The absorption spectra and the second emission spectra may have relationships similar to (1)-(3) as described above.

In diagrams illustrating the absorption spectra versus wavelength, an absorption edge may usually be defined at a wavelength at which the absorption intensity reduces abruptly. In embodiments in which superlattice structure 44 acts as a tunnel junction, the superlattice structure has an absorption edge λ_{TL} in its absorption spectra. In diagrams illustrating the emission spectra versus wavelength, a wavelength corresponding to a maximum emission intensity may usually exist. In embodiments with first active layer 42 having the first emission spectra and the second active layer 52 having the second emission spectra, the first emission spectra and the second emission spectra may have maximum emission intensities at corresponding wavelengths defined as λ_{first}QW and λ_{second}QV, respectively. Taking the first emission spectra as an example, the relationships (1)-(3) as discussed above may be quantitatively described: relationships (1) and (2) fit when λ_{first}QW is greater than λ_{TL}; and relationship (3) fits when λ_{first}QW is less than or equal to λ_{TL}. Similarly, the relationship between the absorption spectra and the second emission spectra may also be quantitatively described by λ_{second}QW and λ_{TL}.

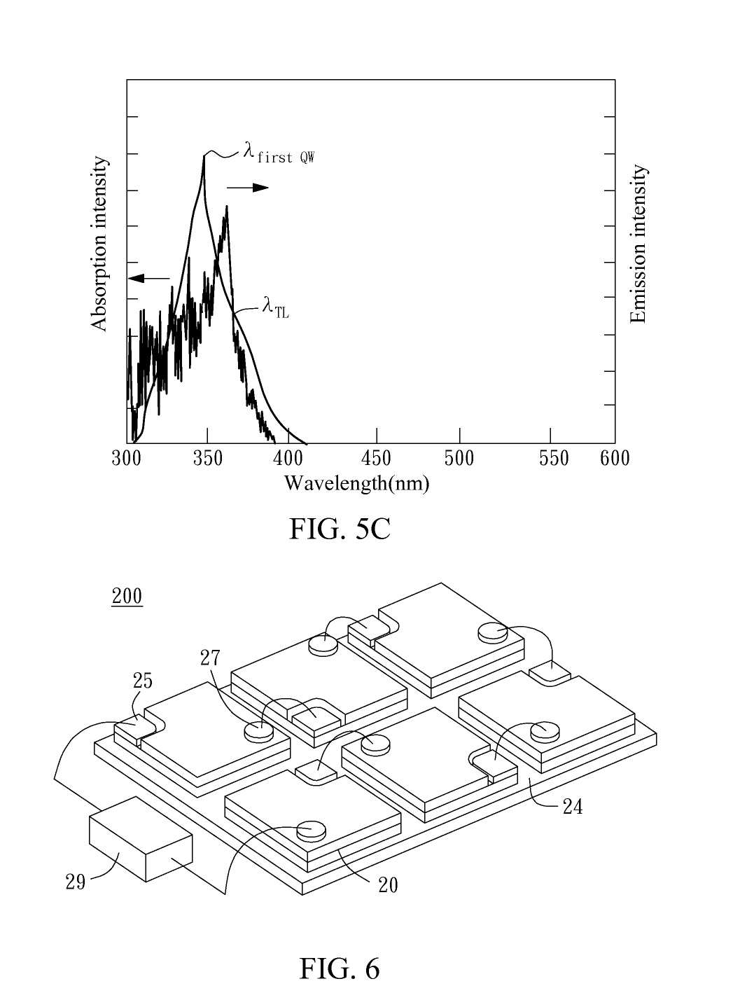

FIG. 6 shows a perspective diagram illustrating an embodiment of LED device 200 that includes a plurality of LED units 20 that are arranged on substrate 24 in an array form. Each LED unit 20 may be similar to the embodiment of LED unit 20 shown in FIG. 1. LED device 200, as shown in FIG. 6, may be referred to as an LED array. First electrode 25 of an LED unit 20 and second electrode 27 of a neighboring LED unit 20 may be electrically connected via solder wire 22 or an interconnect line. The LED units may be connected in series or parallel sequences. Taking the series connected sequence as an example, first electrode 25 of the most front LED unit 20 and second electrode 27 of the most rear LED unit 20 in the sequence are respectively connected to two ends of power supply 29.

It is to be understood the invention is not limited to particular systems described which may, of course, vary. It is also to be understood that the terminology used herein is for the purpose of describing particular embodiments only, and is not intended to be limiting. As used in this specification, the singular forms “a”, “an” and “the” include plural referents unless the content clearly indicates otherwise. Thus, for example, reference to “a device” includes a combination of two or more devices and reference to “a material” includes mixtures of materials.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A light-emitting diode (LED) device having at least one LED unit, the at least one LED unit comprising:
a first LED including an n-side nitride semiconductor layer, a first active layer, and a p-side nitride semiconductor layer;
a second LED including an n-side nitride semiconductor layer, a second active layer, and a p-side nitride semiconductor layer; and
a superlattice structure comprising alternating layers of at least one first sub-layer and at least one second sub-layer, the superlattice structure being located between the p-side nitride semiconductor layer of the first LED and the n-side nitride semiconductor layer of the second LED, the superlattice structure providing a tunnel junction between the first LED and the second LED;
wherein the superlattice structure has an absorption spectra, the first active layer has a first emission spectra, and the second active layer has a second emission spectra, and wherein the absorption spectra is located on a shorter-wavelength side of at least one of the first and the second emission spectra.

2. The LED device of claim 1, wherein the absorption spectra is not overlapped with the first emission spectra.

3. The LED device of claim 1, wherein a total thickness of at least one first sub-layer and at least one second sub-layer of the superlattice structure containing indium is below or equal to 10 nm when the absorption spectra and the first emission spectra overlap each other with overlapping less than or equal to 40%.

4. The LED device of claim 1, wherein a total thickness of at least one first sub-layer and at least one second sub-layer of the superlattice structure containing indium is below or equal to 5 nm when the absorption spectra and the first emission spectra overlap each other with overlapping greater than 40%.

5. The LED device of claim 1, wherein the absorption spectra of the superlattice structure has an absorption edge defined as λ_{TL}, and the first emission spectra of the first active layer has a maximum emission intensity corresponding to a wavelength defined as λ_{first QW}, and wherein λ_{first QW}>λ_{TL}.

6. The LED device of claim 1, wherein the absorption spectra is not overlapped with the second emission spectra.

7. The LED device of claim 1, wherein a total thickness of at least one first sub-layer and at least one second sub-layer of the superlattice structure containing indium is below or equal to 10 nm, when the absorption spectra and the second emission spectra overlap each other with overlapping less than or equal to 40%.

8. The LED device of claim 1, wherein a total thickness of at least one first sub-layer and at least one second sub-layer of the superlattice structure containing indium is below or equal to 5 nm, when the absorption spectra and the second emission spectra overlap each other with overlapping greater than 40%.

9. The LED device of claim 1, wherein the absorption spectra of the superlattice structure has an absorption edge defined as λ_{TL}, and the second emission spectra of the second active layer has a maximum emission intensity corresponding to a wavelength defined as λ_{second QW}, and wherein λ_{second QW}>λ_{TL}.

10. The LED device of claim 1, wherein a combination of the first sub-layer and the second sub-layer comprise one of the following combinations: AlGaN/InGaN, AlGaN/GaN, and GaN/InGaN.

11. The LED device of claim 1, wherein the second sub-layer comprises indium gallium nitride, and an indium concentration of the second sub-layer is less than or equal to 20%.

12. The LED device of claim 1, wherein the first sub-layer comprises aluminum gallium nitride, and an aluminum concentration of the first sub-layer is between 20% and 44%

13. The LED device of claim 1, further comprising:
a first electrode, wherein the n-side nitride semiconductor layer of the first LED comprises n-type gallium nitride electrically connected to the first electrode; and
a second electrode, wherein the p-side nitride semiconductor layer of the second LED comprises p-type gallium nitride electrically connected to the second electrode.

14. The LED device of claim 13, wherein the at least one LED unit comprises a plurality of LED units arranged in an array form, wherein the first electrode and the second electrode of neighboring LED units are electrically connected, thereby resulting in a series or parallel connected sequence of the LED units.

15. A light-emitting diode (LED) device having at least one LED unit, the at least one LED unit comprising:
a first LED including an n-side nitride semiconductor layer, a first active layer, and a p-side nitride semiconductor layer;
a second LED including an n-side nitride semiconductor layer, a second active layer, and a p-side nitride semiconductor layer; and
a superlattice structure comprising alternating layers of at least one first sub-layer and at least one second sub-layer, the superlattice structure being located between the p-side nitride semiconductor layer of the first LED and the n-side nitride semiconductor layer of the second LED, the superlattice structure providing a tunnel junction between the first LED and the second LED;
wherein the superlattice structure has an absorption spectra having an absorption edge defined as λ_{TL}, the first active layer has a first emission spectra having a maximum emission intensity corresponding to a wavelength defined as λ_{first QW}, and the second active layer has a second emission spectra having a maximum emission intensity corresponding to a wavelength defined as λ_{second QW};
wherein a total thickness of at least one first sub-layer and at least one second sub-layer of the superlattice structure containing indium is below or equal to 5 nm, when (1) λ_{first QW}≦λ_{TL}; or (2) λ_{second QW}≦λ_{TL}.

16. The LED device of claim 15, wherein the second sub-layer comprises indium gallium nitride, and an indium concentration of the second sub-layer is less than or equal to 20%.

17. The LED device of claim 15, wherein the first sub-layer comprises aluminum gallium nitride, and an aluminum concentration of the first sub-layer is between 20% and 44%.
